(19) United States
(12) Patent Application Publication
(10) Pub. No.: US 2020/0294766 A1
(43) Pub. Date: Sep. 17, 2020

(54) PLASMA GENERATION UNIT AND METHOD OF DISCRIMINATING STATE OF PHYSICAL QUANTITY WHICH IS USED FOR PLASMA GENERATION

(71) Applicant: Tokyo Electron Limited, Tokyo (JP)

(72) Inventors: Ryou SON, Kurokawa-gun (JP); Yuichi KUWAHARA, Kurokawa-gun (JP); Syuntaro TAWARAYA, Kurokawa-gun (JP); Hideo KATO, Kurokawa-gun (JP)

(73) Assignee: Tokyo Electron Limited, Tokyo (JP)

(21) Appl. No.: 16/807,436

(22) Filed: Mar. 3, 2020

(30) Foreign Application Priority Data
Mar. 14, 2019 (JP) 2019-046808

(51) Int. Cl. H01J 37/32

(52) U.S. Cl. CPC H01J 37/3222; H01J 37/32229; H01J 2237/24495; H01J 37/32669; H01J 2237/24585; H01J 37/32238

(57) ABSTRACT

A plasma generation unit according to an exemplary embodiment includes a dielectric window, a slot plate, and a probe group. The slot plate is provided on the dielectric window. The probe group includes a plurality of probes that are electric conductors, is provided in the dielectric window, and is used for detection of a physical quantity around the dielectric window. The dielectric window extends along the slot plate. Each of the plurality of probes is disposed on a circumference of a first circle centered on a reference position of the dielectric window, when viewed from above the dielectric window.

### CROSS-REFERENCE TO RELATED APPLICATIONS

This application is based on and claims the benefit of priority from Japanese Patent Application No. 2019-046808 filed on Mar. 14, 2019 with the Japan Patent Office, the entire contents of which are incorporated herein by reference.

### TECHNICAL FIELD

Exemplary embodiments of the present disclosure relate to a plasma generation unit and a method of discriminating a state of a physical quantity which is used for plasma generation.

### BACKGROUND

In plasma etching, in order to improve productivity even in the miniaturization and increase in diameter of IC manufacturing, there is a case where plasma which is generated by an RLSA (Radial Line Slot Antenna) is used.

Japanese Unexamined Patent Publication No. 2013-016443 discloses a technique aimed at improving the in-plane uniformity of a substrate surface processing amount. In this technique, an antenna includes a dielectric window and a slot plate provided on one surface of the dielectric window. The other surface of the dielectric window has a flat surface surrounded by a first recessed portion having an annular shape, and a plurality of second recessed portions formed in the flat surface to surround the position of the centroid of the flat surface. In a case of being viewed from a direction perpendicular to a main surface of the slot plate, the position of the centroid of each of the second recessed portions is located to overlap in each slot of the slot plate.

Japanese Unexamined Patent Publication No. 2015-130325 discloses a technique aimed at improving the in-plane uniformity of plasma. In this technique, a slot plate is disposed on the one surface side of a dielectric window. The other surface of the dielectric window includes a flat surface surrounded by a first recessed portion having an annular shape, and a plurality of second recessed portions formed on the bottom surface of the first recessed portion.

### SUMMARY

In an exemplary embodiment, a plasma generation unit which is used in a plasma processing apparatus is provided. The plasma generation unit includes a dielectric window, a slot plate, and a probe group. The slot plate is provided on the dielectric window. The probe group includes a plurality of probes that are electric conductors, is provided in the dielectric window, and is used for detection of a physical quantity which is used for plasma generation and exists around the dielectric window. The dielectric window extends along the slot plate. Each of the plurality of probes is disposed on a circumference of a first circle centered on a reference position of the dielectric window, when viewed from above the dielectric window.

The foregoing summary is illustrative only and is not intended to be in any way limiting. In addition to the illustrative aspects, exemplary embodiments, and features described above, further aspects, exemplary embodiments, and features will become apparent by reference to the drawings and the following detailed description.

### BRIEF DESCRIPTION OF THE DRAWINGS

FIG. 1 is a diagram showing an example of a configuration of a plasma processing apparatus according to an exemplary embodiment.

FIG. 2 is a diagram showing an example of a configuration of a probe shown in FIG. 1.

FIG. 3 is a diagram showing an example of a disposition aspect of the probe.

FIG. 4 is a diagram showing an example of another disposition aspect of the probe.

FIG. 5 is a diagram showing an example of a configuration of a plasma generation unit according to the exemplary embodiment.

FIG. 6 is a diagram showing an example of a distribution of a physical quantity which is acquired by the probe group shown in FIG. 5.

FIG. 7 is a flowchart showing an example of a method according to an exemplary embodiment.

FIG. 8 is a diagram showing an example of disposition of an electromagnet.

FIG. 9 is a diagram showing an example of a disposition aspect of the probe in a case where a dielectric window is provided with a recessed portion.

### DETAILED DESCRIPTION

In the following detailed description, reference is made to the accompanying drawings, which form a part hereof. The exemplary embodiments described in the detailed description, drawing, and claims are not meant to be limiting. Other exemplary embodiments may be utilized, and other changes may be made, without departing from the spirit or scope of the subject matter presented here.

Hereinafter, various exemplary embodiments will be described. In an exemplary embodiment, a plasma generation unit which is used in a plasma processing apparatus is provided. The plasma generation unit includes a dielectric window, a slot plate, and a probe group. The slot plate is provided on the dielectric window. The probe group includes a plurality of probes that are electric conductors, is provided in the dielectric window, and is used for detection of a physical quantity which is used for plasma generation and exists around the dielectric window. The dielectric window extends along the slot plate. Each of the plurality of probes is disposed on a circumference of a first circle centered on a reference position of the dielectric window, when viewed from above the dielectric window. In this manner, since the plurality of probes of the probe group are disposed on the circumference of the first circle of the dielectric window, the physical quantity around the dielectric window can be detected by the probes over an in-plane in which the dielectric window extends.

In an exemplary embodiment, the slot plate has a circular shape when viewed from above the dielectric window. The reference position overlaps a center of the circular shape of the slot plate when viewed from above the dielectric window.

In an exemplary embodiment, the dielectric window has a disk shape centered on the reference position. The probe group is provided on a side surface of the dielectric window.

In an exemplary embodiment, the probe group is provided on a main surface or a rear surface of the dielectric window. The main surface and the rear surface extend along the slot plate. The rear surface is on a side opposite to the main surface and faces the slot plate.

In an exemplary embodiment, the plurality of probes are disposed at equal intervals on the circumference of the first circle.

In an exemplary embodiment, a peripheral end of the slot plate is located inside a peripheral end of the dielectric window when viewed from above the dielectric window.

In an exemplary embodiment, each of the plurality of probes is disposed outside the slot plate when viewed from above the dielectric window.

In an exemplary embodiment, the dielectric window includes a plurality of recessed portions. The plurality of recessed portions are provided on a main surface of the dielectric window.

In an exemplary embodiment, the distance between one line closest to the recessed portion, among a plurality of lines each connecting each of the plurality of probes and the reference position, and the recessed portion is the same in each of the plurality of recessed portions.

In an exemplary embodiment, the plurality of recessed portions are disposed on a circumference of a second circle centered on the reference position, when viewed from above the dielectric window.

In an exemplary embodiment, the plurality of recessed portions are disposed rotationally symmetrically with respect to the reference position, when viewed from above the dielectric window.

In an exemplary embodiment, the number of the plurality of recessed portions is equal to or greater than the number of the plurality of probes included in the probe group.

In an exemplary embodiment, the plurality of recessed portions have the same shape as each other.

A plasma generation unit according to an exemplary embodiment further includes an acquisition unit. The acquisition unit acquires a distribution of the physical quantity around the dielectric window, based on a plurality of values of the physical quantities detected by the probe group.

A plasma generation unit according to an exemplary embodiment further includes a discrimination unit, and an alarm unit. The acquisition unit acquires an index which is used for discrimination of a state of the physical quantity around the dielectric window, based on the acquired distribution of the physical quantity. The discrimination unit determines whether or not the index satisfies one reference set in advance, which indicates the state of the physical quantity, and discriminates the state of the physical quantity, based on a determination result. The alarm unit outputs an alarm signal in a case where the discrimination unit determines that the index does not satisfy the reference.

In an exemplary embodiment, the index is acquired by using at least one of an average value, a maximum value, a minimum value, and a standard deviation of a plurality of values of the physical quantities detected by the plurality of probes.

A plasma generation unit according to an exemplary embodiment further includes a plurality of electromagnets, and an adjustment unit that adjusts an electric current which is supplied to the electromagnets. Magnetic field intensity of a magnetic field generated by the electromagnet is variable according to the electric current which is supplied to the electromagnet. The adjustment unit adjusts an electric current which is supplied to each of the plurality of electromagnets, based on the distribution of the physical quantity acquired by the acquisition unit.

In an exemplary embodiment, the plurality of electromagnets are disposed above a rear surface of the dielectric window facing the slot plate.

A plasma generation unit according to an exemplary embodiment includes a plurality of the probe groups.

In an exemplary embodiment, a method of discriminating a state of a physical quantity which is used for plasma generation is provided. The method acquires a distribution of a physical quantity which is used for plasma generation and exists around a dielectric window, by using a plurality of probes that are electric conductors provided in the dielectric window in a plasma processing apparatus, at the time of plasma generation in the plasma processing apparatus. An index which is used for discrimination of the state of the physical quantity around the dielectric window is acquired based on the acquired distribution of the physical quantity. The state of the physical quantity is discriminated by determining whether or not the index satisfies one reference set in advance, which indicates the state of the physical quantity. In this manner, the distribution of the physical quantity around the dielectric window is acquired through a plurality of probes disposed over an in-plane where the dielectric window extends. The state of the physical quantity around the dielectric window can be suitably discriminated by using the index which is acquired based on the distribution.

According to the present disclosure, a technique for discriminating a state of a physical quantity which is used for plasma generation can be provided.

Hereinafter, various exemplary embodiments will be described in detail with reference to the drawings. In each drawing, identical or corresponding parts are denoted by the same reference numerals.

A plasma processing apparatus 1 according to an exemplary embodiment is a radial line slot antenna type plasma processing apparatus. The plasma processing apparatus 1 is provided with a cylindrical processing container 2. A processing space S is provided in the interior of the processing container 2. The processing container 2 is electrically grounded. The inner wall surface of the processing container 2 is covered with an insulating protective film 2f such as alumina (Al₂O₃). The material of the processing container 2 is, for example, aluminum.

In the processing space S, a table 3 which is used to place a wafer W thereon is provided at the center of a bottom portion of the processing container 2. The wafer W is held on the upper surface of the table 3. The material of the table 3 is a ceramic material such as alumina or aluminum nitride, for example.

A heater 5 is embedded in the table 3. The wafer W can be heated to a predetermined temperature by the heater 5. The heater 5 is connected to a heater power source 4 through a wire disposed in a support post.

An electrostatic chuck CK is provided on the upper surface of the table 3. The electrostatic chuck CK is provided in the processing space S. The electrostatic chuck CK can electrostatically attract the wafer W placed on the table 3.

A bias power source BV is connected to the electrostatic chuck CK. The bias power source BV can apply bias direct-current power or bias radio frequency power through a matching device MG

An exhaust pipe 11 is provided at the bottom portion of the processing container 2. The exhaust pipe 11 can exhaust a processing gas from an exhaust port 11a below the surface of the wafer W placed on the table 3.

An exhaust device 10 such as a vacuum pump is connected to the exhaust pipe 11 through a pressure control valve PCV. The exhaust device 10 communicates with the interior of the processing container 2 through the pressure control valve PCV. The pressure in the processing container 2 can be adjusted to a predetermined pressure by the pressure control valve PCV and the exhaust device 10.

The plasma processing apparatus 1 includes a plasma generation unit PGS. The plasma generation unit PGS includes a dielectric window 16, a slot plate 20, a probe group PBG, an arithmetic device CT, and a detection device DT.

The dielectric window 16 (a top plate) is provided on a ceiling portion of the processing container 2 with a seal 15 interposed therebetween. The ceiling portion (the processing space S) of the processing container 2 is closed by the dielectric window 16. The seal 15 can be an O-ring or the like for securing airtightness. The material of the dielectric window 16 is permeable to microwaves and can be a dielectric such as quartz (SiO₂), alumina, or aluminum nitride (AlN), for example.

The dielectric window 16 has a disk shape centered on a reference position CP of the dielectric window 16. The reference position CP overlaps a central axis AX of the slot plate 20. A main surface PS of the dielectric window 16 faces the processing space S.

A rear surface RS of the dielectric window 16 is on the side opposite to the main surface PS and faces the slot plate 20. The dielectric window 16 extends along the slot plate 20. The main surface PS and the rear surface RS of the dielectric window 16 extend along the slot plate 20.

The peripheral end of the slot plate 20 is located inside the peripheral end of the dielectric window 16 when viewed from above the dielectric window 16. In other words, the dielectric window 16 covers the slot plate 20 when viewed from above the dielectric window 16.

The slot plate 20 is provided on the dielectric window 16. The slot plate 20 is provided on the rear surface RS of the dielectric window 16. The slot plate 20 has a circular shape when viewed from above the dielectric window 16.

The material of the slot plate 20 is a material having conductivity and can be, for example, copper plated or coated with Ag or Au. In the slot plate 20, a plurality of slots 21 are arranged concentrically with respect to the center of the circular shape of the slot plate 20, when viewed from above the dielectric window 16.

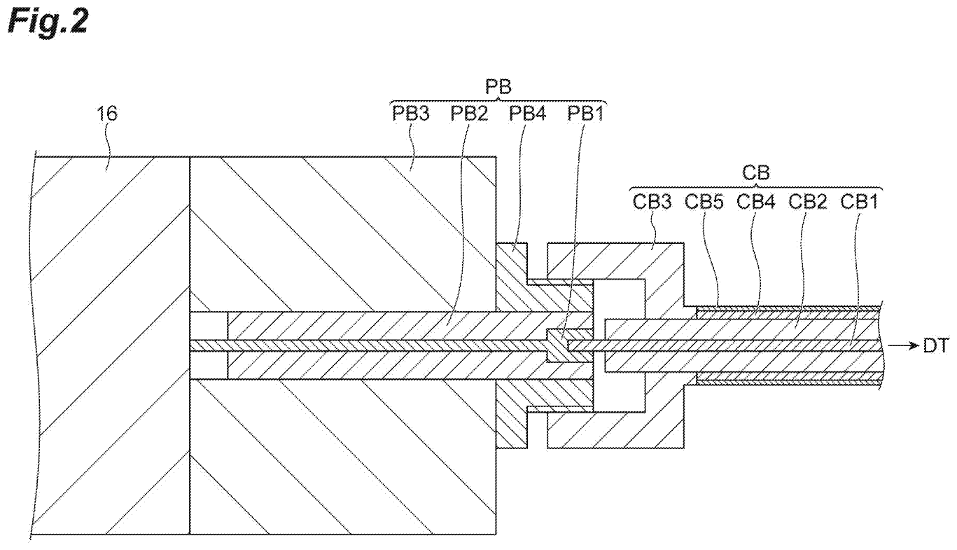

The probe group PBG includes a plurality of probes PB that are electric conductors, is provided in the dielectric window 16, and is used for detection of a physical quantity (hereinafter referred to as a physical quantity PV) around the dielectric window 16. The physical quantity PV described in this specification is a physical quantity which is detected by the probe group PBG is used for plasma generation, and exists to be distributed around the dielectric window 16 at the time of the plasma generation. The physical quantity PV can be, for example, electric field intensity, electric potential, electric power, or the like. As shown in FIG. 2, the probe PB includes an inner conductor PB1, a coating PB2, a base PB3, and a connection member PB4.

The inner conductor PB1 and the coating PB2 are fitted in a hole provided in the center of the base PB3. The inner conductor PB1 and the coating PB2 extend from the inside of the base PB3 onto the base PB3. The inner conductor PB1 is covered with the coating PB2.

The base PB3 is provided in the dielectric window 16. The inner conductor PB1 and the coating PB2 are held by the connection member PB4 on the base PB3.

The material of the inner conductor PB1 has conductivity. The material of the coating PB2 has insulation properties. The material of the base PB3 has conductivity. The material of the connection member PB4 has conductivity.

A coaxial cable CB can be connected to the probe PB. The coaxial cable CB is connected to the detection device DT. The probe PB is connected to the detection device DT through the coaxial cable CB.

The coaxial cable CB includes an inner conductor CB1, a coating CB2, a connection member CB3, an outer conductor CB4, and an outer skin CBS. The inner conductor CB1 comes into contact with an end portion of the inner conductor PB1 on the base PB3. The inner conductor PB1 and the inner conductor CB1 are electrically connected to each other. The inner conductor CB1 is covered with the coating CB2. The inner conductor CB1 and the coating CB2 are held by the connection member CB3 on the probe PB.

The connection member CB3 has a recess shape. The inner conductor CB1 protruding from the inside of the recess shape of the connection member CB3 reaches the inner conductor PB1 and comes into contact with the inner conductor PB1. The connection member PB4 is fitted into the recess shape of the connection member CB3, whereby the connection member CB3 is held on the connection member PB4.

The probe group PBG (the plurality of probes PB) can be provided on a side surface SS of the dielectric window 16 in an exemplary embodiment. The side surface SS extends to intersect the main surface PS and the rear surface RS, and extends between the peripheral end of the main surface PS and the peripheral end of the rear surface RS. Each of the plurality of probes PB of the probe group PBG is disposed outside the slot plate 20 when viewed from above the dielectric window 16.

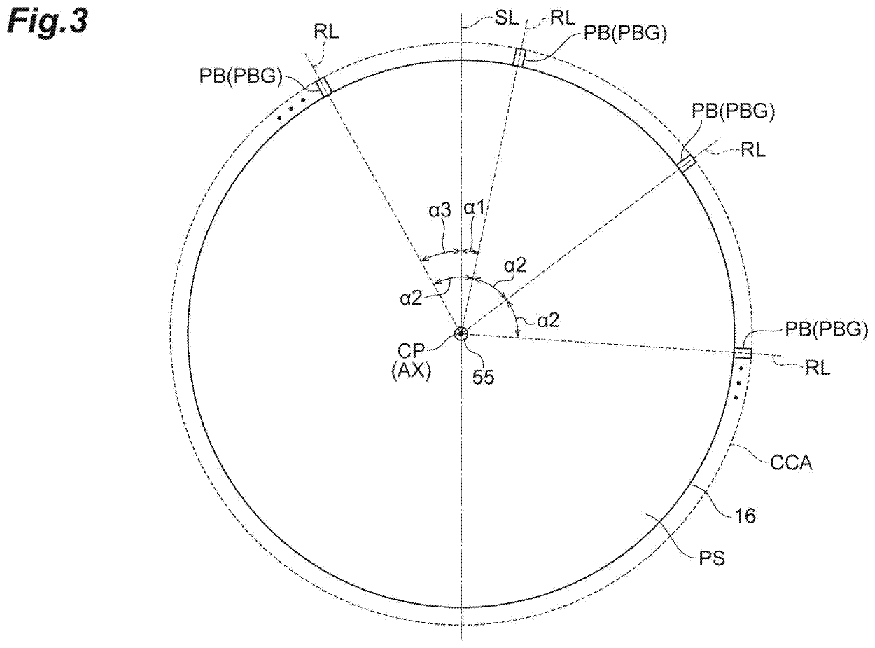

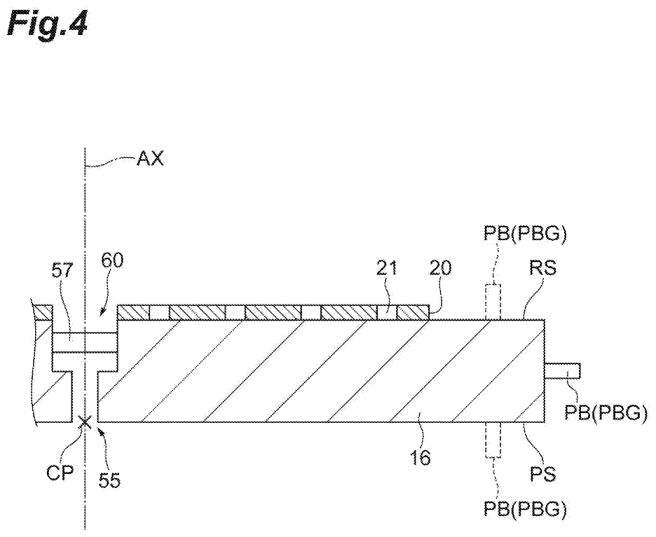

An example of an aspect of the disposition of the plurality of probes PB is shown in FIG. 3. FIG. 3 shows an aspect of the main surface PS when viewed from above the dielectric window 16. The probe group PBG is provided on the side surface SS of the dielectric window 16. However, there is no limitation thereto, and the probe group PBG may be provided on the main surface PS or the rear surface RS of the dielectric window 16, as shown in FIG. 4.

Each of the plurality of probes PB is disposed (for example, at equal intervals) on the circumference of a first circle CCA centered on the reference position CP of the dielectric window 16, when viewed from above the dielectric window 16. The main surface PS of the dielectric window 16 shown in FIG. 3 has a circular shape.

In an exemplary embodiment, when viewed from above the dielectric window 16, the reference position CP (the center of the first circle CCA) of the dielectric window 16 overlaps the center of the circular shape of the main surface PS, and can be located in a central introduction part 55. The reference position CP overlaps the center of the circular shape of the slot plate 20 when viewed from above the dielectric window 16.

In an exemplary embodiment, the plurality of probes PB can be disposed periodically (for example, at equal intervals) in accordance with the disposition of the plurality of slots 21 on the circumference of the first circle CCA.

A reference line SL and a plurality of lines RL are shown in FIG. 3. The reference line SL extends along the main surface PS through the reference position CP when viewed from above the dielectric window 16. The line RL is a line connecting the probe PB and the reference position CP (a line extending from the probe PB to the reference position CP through the probe PB).

An angle α1, an angle α2, and an angle α3 are shown in FIG. 3. The angle α1 is an angle (an acute angle) formed between the line RL passing through the probe PB closest to the reference line SL and the reference line SL. The angle α2 is an angle (an acute angle) formed between two lines RL respectively passing through two probes PB adjacent to each other on the first circle CCA. The angle α3 is an angle (an acute angle) formed between the line RL passing through the probe PB which is first located beyond the reference line SL in a case where the opposite side of the reference line SL is viewed along the first circle CCA from the probe PB closest to the reference line SL, and the reference line SL.

The plurality of angles α2 are all equal to each other (for example, in an aspect in which the plurality of probes PB are periodically disposed on the circumference of the first circle CCA). However, there can also be a case where at least some of the plurality of angles α2 are different.

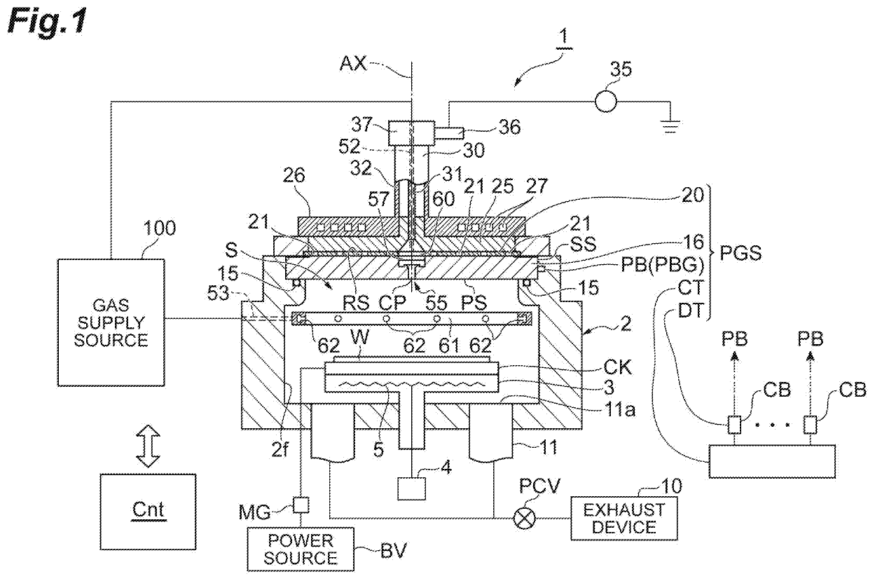

Description will be made returning to FIG. 1. A dielectric plate 25 which is used for compression of the wavelength of a microwave is disposed on the upper surface of the slot plate 20. The material of the dielectric plate 25 can be, for example, a dielectric such as quartz, alumina, or aluminum nitride. The dielectric plate 25 is covered with a conductive cover 26.

An annular heat medium flow path 27 is provided in the cover 26. The cover 26 and the dielectric plate 25 can be adjusted to a predetermined temperature by the heat medium flowing through the heat medium flow path 27.

A coaxial waveguide 30 that propagates microwaves is connected to the center of the cover 26. The coaxial waveguide 30 includes an inner conductor 31 and an outer conductor 32. The inner conductor 31 penetrates the center of the dielectric plate 25 and is connected to the center of the slot plate 20.

A microwave generator 35 is connected to the coaxial waveguide 30 through a mode converter 37 and a rectangular waveguide 36. The microwave that can be used in the plasma processing apparatus 1 can be a microwave of 2.45 [GHz], 860 [MHz], 915 [MHz], 8.35 [GHz], or the like. For example, the microwave of 2.45 [GHz] has a wavelength of about 12 [cm] in a vacuum and has a wavelength in a range of about 3 to 4 [cm] in the dielectric window 16 made of alumina.

The microwave generated by the microwave generator 35 sequentially propagates through the rectangular waveguide 36, the mode converter 37, the coaxial waveguide 30, and the dielectric plate 25. The rectangular waveguide 36, the mode converter 37, the coaxial waveguide 30, and the dielectric plate 25 function as a microwave introduction path.

The microwave propagating through the dielectric plate 25 is supplied from the plurality of slots 21 of the slot plate 20 into the processing space S through the main surface PS of the dielectric window 16. An electric field is formed below the dielectric window 16 in the processing space S by the microwave, and the processing gas in the processing space S can be turned into plasma.

The lower end of the inner conductor 31 which is connected to the slot plate 20 has a truncated cone shape. Therefore, the microwave can efficiently propagate from the coaxial waveguide 30 to the dielectric plate 25 and the slot plate 20 without a loss.

In the plasma processing apparatus 1, the microwave is supplied by a radial line slot antenna. The radial line slot antenna diffuses plasma having an energy of a relatively high electron temperature generated (in a plasma excitation region) just below the dielectric window 16, thereby forming plasma having a relatively low electron temperature in a range of about 1 to 2 [eV] (in a diffusion plasma region) just above the wafer W.

That is, the distribution of the electron temperature of the plasma which is generated by the radial line slot antenna can be expressed as a function of the distance from the dielectric window 16, unlike the plasma which is generated by a parallel flat plate or the like. More specifically, an electron temperature in a range of several [eV] to 10 [eV] just below the dielectric window 16 can be attenuated to an electron temperature in a range of about 1 to 2 [eV] in the wafer W. Since the processing of the wafer W is performed in a region where the electron temperature of the plasma is low (the diffusion plasma region), large damage such as a recess cannot occur in the wafer W.

In a case where the processing gas is supplied to a region where the electron temperature of the plasma is high (the plasma excitation region), the processing gas is easily excited and dissociated. On the other hand, in a case where the processing gas is supplied to a region where the electron temperature of the plasma is low (the diffusion plasma region), the degree of dissociation can be suppressed compared to a case where the processing gas is supplied near the plasma excitation region.

The central introduction part 55 is provided in the center of the dielectric window 16 of the ceiling portion of the processing container 2. The central introduction part 55 can introduce the processing gas to the central portion of the wafer W. The central introduction part 55 is connected to a supply path 52. The supply path 52 is provided in the inner conductor 31 of the coaxial waveguide 30. The central introduction part 55 is connected to a gas supply source 100.

The central introduction part 55 has a block 57 and a gas reservoir 60. The block 57 is fitted into a cylindrical space portion provided in the center of the dielectric window 16. The block 57 is electrically installed and has a columnar shape. The material of the block 57 is a conductive material such as aluminum, for example.

The gas reservoir 60 is provided between the lower surface of the inner conductor 31 of the coaxial waveguide 30 and the upper surface of the block 57. A plurality of central introduction ports penetrating in an up-down direction are formed in the block 57. The planar shape of the central introduction port can be formed into a perfect circle or a long hole in consideration of necessary conductance or the like. The aluminum block 57 can be coated with anodized and coated alumina, yttria (Y₂O₃), or the like.

The processing gas which is supplied from the gas supply source 100 to the gas reservoir 60 through the supply path 52 penetrating the inner conductor 31 is diffused into the gas reservoir 60 and then sprayed downward from the plurality of central introduction ports of the block 57 and toward the central portion of the wafer W.

A peripheral introduction part 61 is provided in the processing space S inside the processing container 2. The peripheral introduction part 61 is disposed to surround the periphery on the upper side of the wafer W. The peripheral introduction part 61 is disposed below the central introduction port disposed at the ceiling portion and above the wafer W placed on the table 3. The peripheral introduction part 61 is connected to the gas supply source 100. The peripheral introduction part 61 can supply the processing gas from the gas supply source 100 to the peripheral portion of the wafer W.

The peripheral introduction part 61 has a ring shape. The peripheral introduction part 61 has the shape of an annular hollow pipe. A plurality of peripheral introduction ports 62 are provided at certain intervals in the circumferential direction on the inner periphery side of the peripheral introduction part 61. The material of the peripheral introduction part 61 can be, for example, quartz. The peripheral introduction port 62 can have a function of spraying the processing gas toward the center of the peripheral introduction part 61.

A supply path 53 made of stainless steel penetrates the side surface of the processing container 2. The supply path 53 is provided between the gas supply source 100 and the peripheral introduction part 61 and is connected to the gas supply source 100 and the peripheral introduction part 61. The processing gas which is supplied from the gas supply source 100 to the interior of the peripheral introduction part 61 through the supply path 53 is diffused into the space in the interior of the peripheral introduction part 61 and then sprayed from the plurality of peripheral introduction ports 62 toward the inside of the peripheral introduction part 61. The processing gas sprayed from the plurality of peripheral introduction ports 62 is supplied to the upper portion of the periphery of the wafer W. In the plasma processing apparatus 1, it is also possible to provide the plurality of peripheral introduction ports 62 on the inner side surface of the processing container 2, instead of providing the ring-shaped peripheral introduction part 61 described above.

In an exemplary embodiment, the reference position CP (the center) of the dielectric window 16 and the center of each of the slot plate 20, the dielectric plate 25, the cover 26, the inner conductor 31, and the supply path 52 can overlap each other when viewed from above the dielectric window 16. More specifically, the reference position CP (the center) of the dielectric window 16 and the center of each of the slot plate 20, the dielectric plate 25, the cover 26, the inner conductor 31, and the supply path 52 overlap the central axis AX of the processing container 2.

A control unit Cnt includes a CPU, a RAM, a ROM, and the like, and comprehensively controls the operation of the plasma processing apparatus 1, for example, by causing the CPU to execute a computer program. The control unit Cnt controls particularly the operations of the microwave generator 35, the pressure control valve PCV, and the bias power source By. The control unit Cnt may have a configuration including the arithmetic device CT.

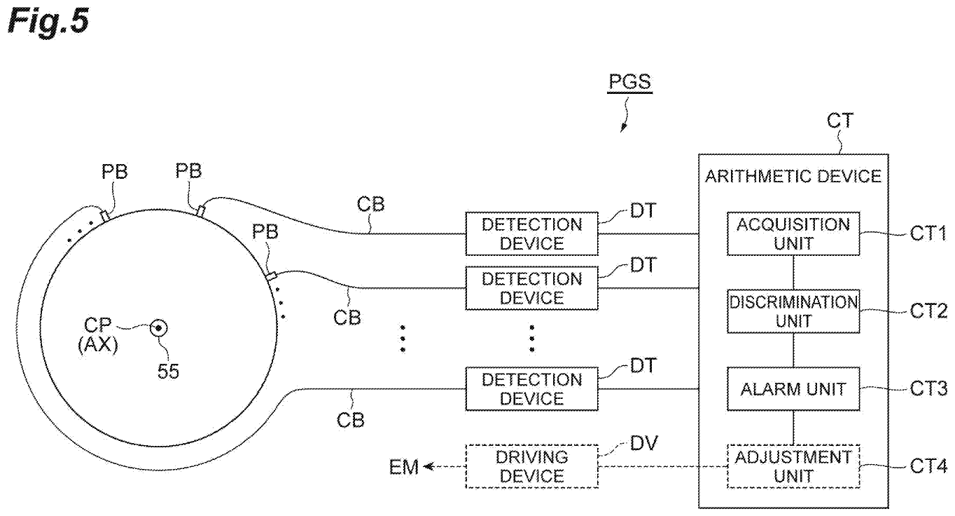

As shown in FIG. 5, each of the plurality of probes PB of the probe group PBG is connected to each of the plurality of detection devices DT through each of the plurality of coaxial cables CB. The plurality of detection devices DT are connected to the arithmetic device CT.

The detection device DT detects a signal which is output from the probe PB connected to the detection device DT and sends the detected signal to the arithmetic device CT. The plurality of signals which are output from the plurality of probes PB represent the physical quantities PV around the dielectric window 16, which are detected by the probe group PBG For example, there can be a case where the detection device DT has a wave detector and an oscilloscope connected to the wave detector.

The arithmetic device CT includes a computer having a CPU, a ROM, a RAM, and the like, and analyzes a plurality of signals sent from the plurality of detection devices DT. The arithmetic device CT realizes various functions of an acquisition unit CT1, a discrimination unit CT2, an alarm unit CT3, and the like by driving the computer provided in the arithmetic device CT.

The acquisition unit CT1 acquires the distribution of the physical quantity PV around the dielectric window 16, based on a plurality of values of the physical quantities PV detected by the probe group PBG The acquisition unit CT1 acquires an index which is used for the discrimination of the state of the physical quantity PV around the dielectric window 16, based on the acquired distribution of the physical quantity PV.

The index is acquired by using at least one of an average value (Ave), a maximum value, a minimum value, and a standard deviation (σ) of the plurality of values of the physical quantities PV detected by the plurality of probes PB. The index can be, for example, any one of an average value, a maximum value, a minimum value, and a value indicating variation of the physical quantities PV detected by the plurality of probes PB.

For example, a value obtained by multiplying a coefficient of variation by an integer (for example, three times) can be used for the value indicating variation of the physical quantities PV. The coefficient of variation is a value (σ/Ave) obtained by dividing the standard deviation by the average value.

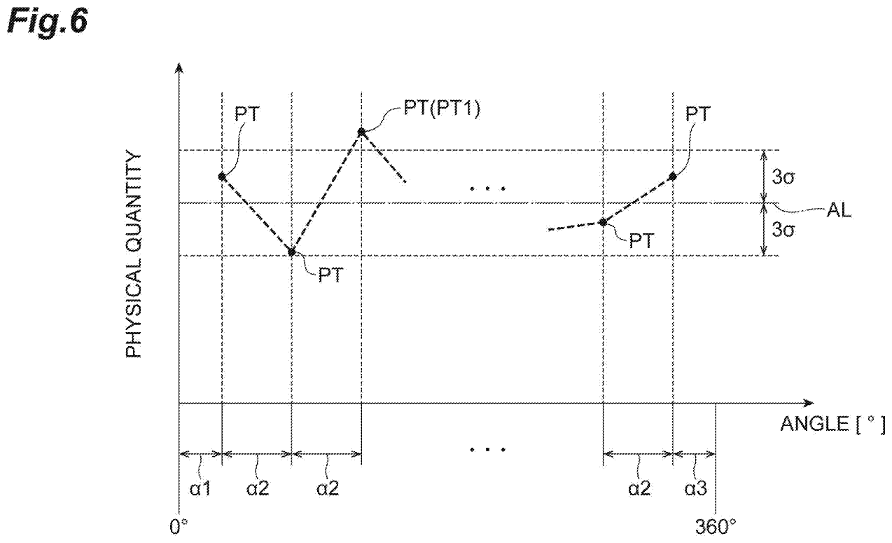

FIG. 6 shows an example of the values of the physical quantities PV detected by the plurality of probes PB. The horizontal axis of FIG. 6 represents the position of the probe PB (the angle shown in FIG. 3 and the angle between the line RL passing through the probe PB and the reference line SL) [°], and the vertical axis represents the physical quantity PV. Each of a plurality of points PT indicates the value of the physical quantity PV detected by each of the plurality of probes PB. A line AL indicates the average value of the values of the physical quantities PV detected by each of the plurality of probes PB.

σ is the standard deviation of the values of the physical quantities PV detected by each of the plurality of probes PB. 3σ is a value obtained by tripling σ. In FIG. 6, as an example, 3σ is shown. However, there is no limitation thereto, and it can be σ, 2σ (a value obtained by doubling σ), or the like.

Description will be made returning to FIG. 5. The discrimination unit CT2 determines whether or not the index satisfies one reference set in advance (hereinafter, referred to as a reference SV), which indicates the state of the physical quantity PV around the dielectric window 16. The discrimination unit CT2 discriminates the state of the physical quantity PV around the dielectric window 16, based on the result of the determination of whether or not the index satisfies the reference SV. The reference SV is a value corresponding to the index which is used by the discrimination unit CT2, and is different for each content of the index. The alarm unit CT3 outputs an alarm signal to an external device (for example, a display, a speaker, or the like) in a case where the discrimination unit CT2 determines that the index does not satisfy the reference SV.

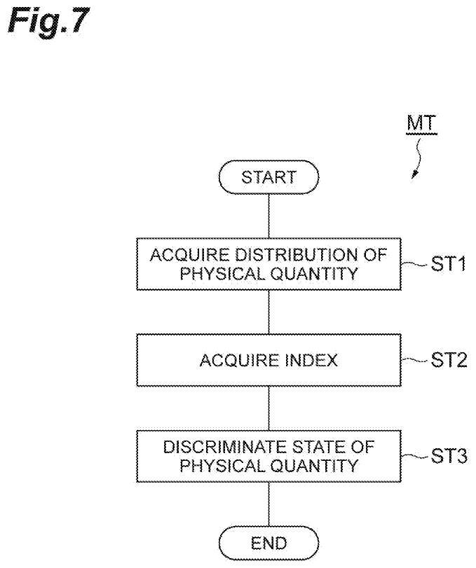

The arithmetic device CT acquires signals (signals indicating the values of the detected physical quantities PV) which are sent from the plurality of detection devices DT at every timing set in advance at the time of plasma generation in the plasma processing apparatus 1, and executes the method MT shown in FIG. 7. The method MT is an exemplary embodiment of the method of discriminating the state of the physical quantity PV which is used for plasma generation. The method MT shown in FIG. 7 is executed by the computer of the arithmetic device CT (the acquisition unit CT1, the discrimination unit CT2, and the like shown in FIG. 5). The method MT includes step ST1 to step ST3.

First, a plurality of signals which are sent from the plurality of detection devices DT at the time of the plasma generation in the plasma processing apparatus 1 are acquired by the arithmetic device CT. The acquisition unit CT1 acquires the distribution of the physical quantity PV which is used for plasma generation and exists around the dielectric window 16, by using the probe group PBG (the plurality of probes PB) provided in the dielectric window 16, based on the plurality of signals acquired from the plurality of detection devices DT (step ST1).

Subsequent to step ST1, the acquisition unit CT1 acquires the index which is used for the discrimination of the state of the physical quantity PV around the dielectric window 16, based on the distribution of the physical quantity PV acquired in step ST1 (step ST2).

Subsequent to step ST2, the discrimination unit CT2 determines whether or not the index acquired in step ST2 satisfies one reference SV set in advance, which indicates the state of the physical quantity PV around the dielectric window 16. By this determination, the state of the physical quantity PV around the dielectric window 16 is discriminated (step ST3). In step ST3, in a case where the discrimination unit CT2 determines that the index does not satisfy the reference SV, the alarm unit CT3 outputs an alarm signal to an external device.

Steps ST1 to ST3 described above are executed, whereby the state of the physical quantity PV around the dielectric window 16 is discriminated, and in a case where the state of the physical quantity PV around the dielectric window 16 does not satisfy the reference, an alarm signal is output to the external device as necessary.

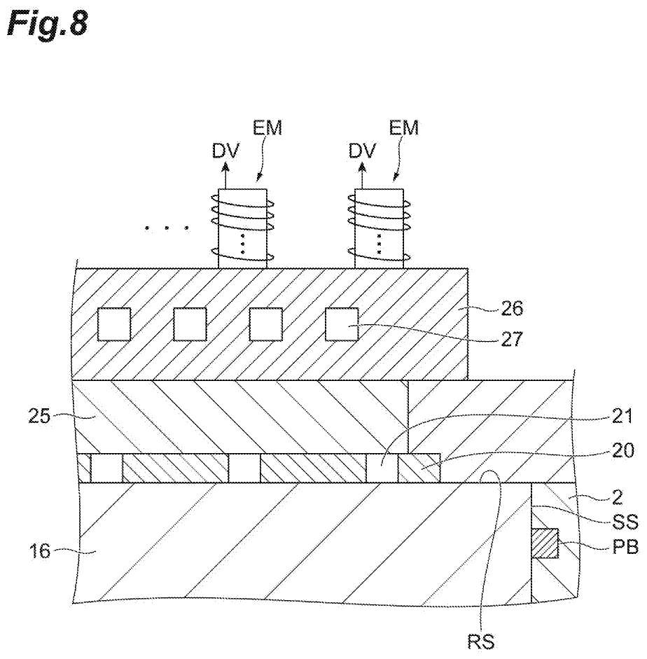

(Modification Example) As shown in FIG. 8, the plasma processing apparatus 1 may further include a driving device DV and a plurality of electromagnets EM. In this case, the arithmetic device CT further includes an adjustment unit CT4. The magnetic field intensity of a magnetic field which is generated by the electromagnet EM is variable according to an electric current which is supplied to the electromagnet EM. The driving device DV supplies an electric current to the electromagnet EM. The adjustment unit CT4 adjusts the electric current which is supplied to each of the plurality of electromagnets EM, based on the distribution of the physical quantity PV which is acquired by the acquisition unit CT1.

For example, a case where the physical quantity PV (a point PT1 shown in FIG. 6) is detected outside the range of “the average value (Ave)” ±“3 times the standard deviation (3σ)” (the range of Ave-3σ or more and Ave+3σ or less) is considered. In this case, the adjustment unit CT4 adjusts the electric current which is supplied to the electromagnet EM which is at the position (or a position closest to the position) of the probe PB in which the physical quantity PV (the point PT1 shown in FIG. 6) has been detected, thereby adjusting plasma density at the position.

The plurality of electromagnets EM are disposed above the rear surface RS of the dielectric window 16, as shown in FIG. 8, for example. More specifically, the plurality of electromagnets EM are disposed, for example, on the surface of the cover 26 which is disposed above the rear surface RS of the dielectric window 16. The plurality of electromagnets EM are disposed such that the plasma density can be adjusted in detail over the lower part of the dielectric window 16.

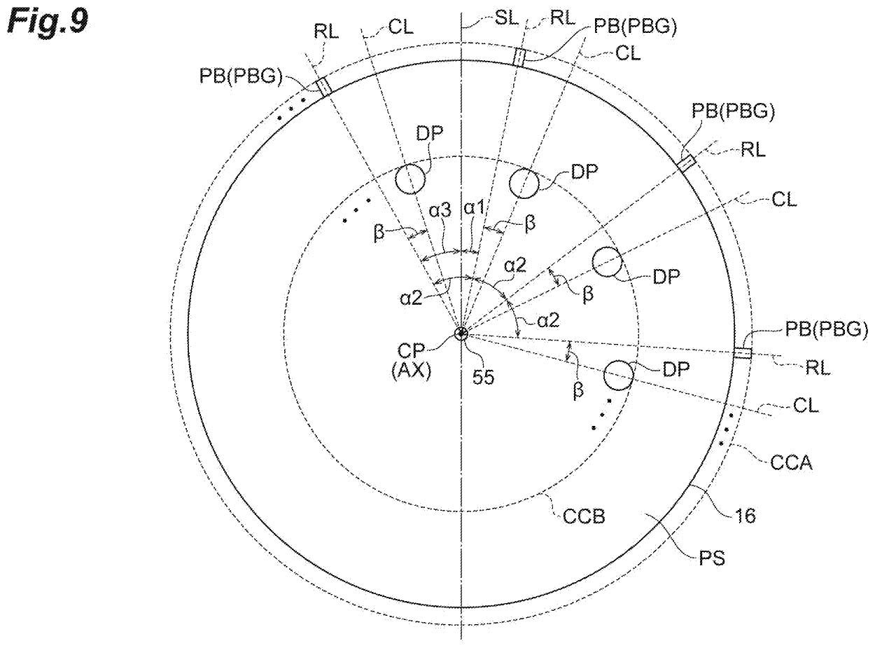

The dielectric window 16 can include a plurality of recessed portions DP, as shown in FIG. 9. The plurality of recessed portions DP are provided on the main surface PS of the dielectric window 16. A second circle CCB, a line CL, and an angle β are shown in FIG. 9.

The plurality of recessed portions DP are disposed on the circumference of the second circle CCB centered on the reference position CP when viewed from above the dielectric window 16. The line CL shown in FIG. 9 is a line connecting the recessed portion DP and the reference position CP (a line extending from the recessed portion DP to the reference position CP through the recessed portion DP).

The angle β is an angle between a set of line RL and line CL adjacent to each other and closest to each other. The angle β can be in the range of 0 [°] or more and less than an angle α2 [°].

For example, all the angles β are the same. In this case, the plurality of recessed portions DP are disposed rotationally symmetrically with respect to the reference position CP, when viewed from above the dielectric window 16. More specifically, the distance between one line RL closest to a specific recessed portion DP among the plurality of lines RL and the specific recessed portion DP (the angle β between the one line RL and the line CL passing through the specific recessed portion DP) is the same in each of the plurality of recessed portions DP.

The number of the plurality of recessed portions DP is equal to or greater than the number of the plurality of probes PB included in the probe group PBG The number of the plurality of recessed portions DP can be, for example, a positive integer multiple (one time, two times, or the like) of the number of the plurality of probes PB included in the probe group PBG Further, in an exemplary embodiment, the plurality of recessed portions DP can have the same shape as each other.

According to the plasma generation unit PGS as described above, the plurality of probes PB of the probe group PBG are disposed on the circumference of the first circle CCA of the dielectric window 16. Therefore, the physical quantity PV around the dielectric window 16 can be detected by the probe PB over the in-plane in which the probe PB extends.

Further, according to the method MT as described above, the distribution of the physical quantity PV around the dielectric window 16 is acquired through the plurality of probes PB disposed over the in-plane in which the dielectric window 16 extends. The state of the physical quantity PV around the dielectric window 16 can be suitably discriminated by using the index which is obtained based on the distribution.

The number of the probe groups PBG is not limited to one and may be plural. In this case, the plurality of probe groups PBG can mutually have a rotationally symmetric relationship with the reference position CP as the center, when viewed from above the dielectric window 16.

Various exemplary embodiments have been described above. However, the present disclosure is not limited to the exemplary embodiments described above and various omissions, substitutions, and changes may be made. Further, elements in different exemplary embodiments can be combined to form other exemplary embodiments.

The present disclosure provides a technique for discriminating the state of the physical quantity which is used for plasma generation.

Although various exemplary embodiments have been described above, various modified aspect may be configured without being limited to the above-described exemplary embodiments.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A plasma generation unit which is used in a plasma processing apparatus, comprising:
a dielectric window;
a slot plate; and
a probe group,
wherein the slot plate is provided on the dielectric window,
the probe group includes a plurality of probes that are electric conductors, is provided in the dielectric window, and is used for detection of a physical quantity used for plasma generation and existing around the dielectric window,
the dielectric window extends along the slot plate, and
each of the plurality of probes is disposed on a circumference of a first circle centered on a reference position of the dielectric window, when viewed from above the dielectric window.

2. The plasma generation unit according to claim 1, wherein the slot plate has a circular shape when viewed from above the dielectric window, and the reference position overlaps a center of the circular shape of the slot plate when viewed from above the dielectric window.

3. The plasma generation unit according to claim 1, wherein the dielectric window has a disk shape centered on the reference position, and the probe group is provided on a side surface of the dielectric window.

4. The plasma generation unit according to claim 1, wherein the probe group is provided on a main surface or a rear surface of the dielectric window, the main surface and the rear surface extend along the slot plate, and the rear surface is on a side opposite to the main surface and faces the slot plate.

5. The plasma generation unit according to claim 1, wherein the plurality of probes are disposed at equal intervals on the circumference of the first circle.

6. The plasma generation unit according to claim 1, wherein a peripheral end of the slot plate is located inside a peripheral end of the dielectric window when viewed from above the dielectric window.

7. The plasma generation unit according to claim 1, wherein each of the plurality of probes is disposed outside the slot plate when viewed from above the dielectric window.

8. The plasma generation unit according to claim 1, wherein the dielectric window includes a plurality of recessed portions, and the plurality of recessed portions are provided on a main surface of the dielectric window.

9. The plasma generation unit according to claim 8, wherein a distance between one line closest to the recessed portion, among a plurality of lines connecting each of the plurality of probes and the reference position, and the recessed portion is the same in each of the plurality of recessed portions.

10. The plasma generation unit according to claim 8, wherein the plurality of recessed portions are disposed on a circumference of a second circle centered on the reference position, when viewed from above the dielectric window.

11. The plasma generation unit according to claim 8, wherein the plurality of recessed portions are disposed rotationally symmetrically with respect to the reference position, when viewed from above the dielectric window.

12. The plasma generation unit according to claim 8, wherein the number of the plurality of recessed portions is equal to or greater than the number of the plurality of probes included in the probe group.

13. The plasma generation unit according to claim 8, wherein the plurality of recessed portions have the same shape as each other.

14. The plasma generation unit according to claim 1, further comprising:
an acquisition unit,
wherein the acquisition unit acquires a distribution of the physical quantity around the dielectric window, based on a plurality of values of the physical quantities detected by the probe group.

15. The plasma generation unit according to claim 14, further comprising:
a discrimination unit; and
an alarm unit,
wherein the acquisition unit acquires an index which is used for discrimination of a state of the physical quantity around the dielectric window, based on the acquired distribution of the physical quantity,
the discrimination unit determines whether or not the index satisfies one reference set in advance, which indicates the state of the physical quantity and discriminates the state of the physical quantity, based on a determination result, and
the alarm unit outputs an alarm signal in a case where the discrimination unit determines that the index does not satisfy the reference.

16. The plasma generation unit according to claim 15, wherein the index is acquired by using at least one of an average value, a maximum value, a minimum value, and a standard deviation of a plurality of values of the physical quantities detected by the plurality of probes.

17. The plasma generation unit according to claim 14, further comprising:
a plurality of electromagnets; and
an adjustment unit adjusting an electric current which is supplied to the electromagnets,
wherein magnetic field intensity of a magnetic field generated by the electromagnet is variable according to the electric current which is supplied to the electromagnet, and
the adjustment unit adjusts an electric current which is supplied to each of the plurality of electromagnets, based on the distribution of the physical quantity acquired by the acquisition unit.

18. The plasma generation unit according to claim 17, wherein the plurality of electromagnets are disposed above a rear surface of the dielectric window facing the slot plate.

19. The plasma generation unit according to claim 1, comprising:
a plurality of the probe groups.

20. A method of discriminating a state of a physical quantity which is used for plasma generation, the method comprising:
acquiring a distribution of a physical quantity which is used for plasma generation and exists around a dielectric window, by using a plurality of probes that are electric conductors provided in the dielectric window in a plasma processing apparatus, at the time of plasma generation in the plasma processing apparatus;
acquiring an index which is used for discrimination of a state of the physical quantity around the dielectric window, based on the acquired distribution of the physical quantity; and
discriminating the state of the physical quantity by determining whether or not the index satisfies one reference set in advance, which indicates the state of the physical quantity.
